(19) United States
(12) Patent Application Publication
(10) Pub. No.: US 2022/0026608 A1
(43) Pub. Date: Jan. 27, 2022

(54) LIGHT CONTROL MEMBER, DISPLAY DEVICE AND METHOD OF MANUFACTURING DISPLAY DEVICE

(71) Applicant: Samsung Display Co., LTD., Yongin-si (KR)

(72) Inventors: Bo Kwang SONG, Hwaseong-si (KR); Youn Joon KIM, Seoul (KR); Jung Woo PARK, Seoul (KR)

(21) Appl. No.: 17/381,311

(22) Filed: Jul. 21, 2021

(30) Foreign Application Priority Data
Jul. 22, 2020 (KR) 10-2020-0090836

(51) Int. Cl. G02B 5/04; G02B 5/00

(52) U.S. Cl. CPC G02B 5/04; G02B 1/113; G02B 5/003

(57) ABSTRACT

A light control member comprises a substrate; an anisotropic prism disposed on the substrate and including a first side surface extending at a first angle and a second side surface extending at a second angle greater than the first angle, with respect to one surface of the substrate; an absorptive pattern disposed on the second side surface of the anisotropic prism; and an absorptive pattern protective layer disposed on the second side surface of the anisotropic prism and the absorptive pattern.

This application claims priority to Korean Patent Application No. 10-2020-0090836, filed on Jul. 22, 2020, and all the benefits accruing therefrom under 35 U.S.C. § 119, the content of which in its entirety is herein incorporated by reference.

### BACKGROUND

### 1. Field

The disclosure relates to a light control member, a display device and a method of manufacturing the display device.

### 2. Description of the Related Art

A display device is a device for displaying an image, and includes a display panel, such as an organic light emitting display panel or a liquid crystal display panel.

An emission angle of light emitted through a display surface of the display device may be a viewing angle from a user's point of view. When the user's viewing angle is wide, the user may be allowed to see an image displayed on the display surface without distortion regardless of his or her position.

### SUMMARY

When a display device is used in a specific environment, such as a driving environment, it may be desired to limit the viewing angle of a user. Accordingly, to control the viewing angle of the user, the display device may include a light control member for controlling the emission angle, i.e., the viewing angle, of the emitted light disposed on a display panel.

Aspects of the disclosure provide a light control member capable of easily controlling a viewing angle to a desired angle.

Aspects of the disclosure also provide a display device including a light control member capable of easily controlling a viewing angle to a desired angle.

Aspects of the disclosure also provide a method of manufacturing a display device including a light control member capable of easily controlling a viewing angle to a desired angle.

According to an embodiment, a light control member includes a substrate; an anisotropic prism disposed on the substrate, where the anisotropic prism includes a first side surface extending at a first angle with respect to one surface of the substrate, and a second side surface extending at a second angle greater than the first angle with respect to the one surface of the substrate; an absorptive pattern disposed on the second side surface of the anisotropic prism; and an absorptive pattern protective layer disposed on the second side surface of the anisotropic prism and the absorptive pattern.

According to an embodiment, a light control member includes a substrate; an anisotropic prism disposed on the substrate, where the anisotropic prism includes a first side surface extending at a first angle with respect to one surface of the substrate, and a second side surface extending at a second angle greater than the first angle with respect to the one surface of the substrate; and an absorptive pattern disposed on the second side surface of the anisotropic prism, wherein the absorptive pattern is disposed directly on the second side surface, and the absorptive pattern includes a metal layer.

According to an embodiment, a display device includes a light emitting element disposed on a first substrate; and a light control member disposed on the light emitting element. In such an embodiment, the light control member includes: a substrate; an anisotropic prism disposed on the substrate, where the anisotropic prism includes a first side surface extending at a first angle with respect to one surface of the substrate, and a second side surface extending at a second angle greater than the first angle with respect to the one surface of the substrate; an absorptive pattern disposed on the second side surface of the anisotropic prism; and an absorptive pattern protective layer disposed on the second side surface of the anisotropic prism and the absorptive pattern.

According to an embodiment, a method of manufacturing a display device includes forming a light control member; and bonding the light control member and a display panel to each other, where the forming the light control member includes: providing, on a substrate, an anisotropic prism including a first side surface extending at a first angle with respect to one surface of the substrate and a second side surface extending at a second angle greater than the first angle with respect to the one surface of the substrate; providing an absorptive pattern on the second side surface of the anisotropic prism; and providing an absorptive pattern protective layer disposed on the second side surface of the anisotropic prism and the absorptive pattern.

In embodiments of the light control member, the display device, and the method of manufacturing the display device according to the invention, the viewing angle may be easily controlled to a desired angle.

In embodiments of the light control member, the display device, and the method of manufacturing the display device according to the invention, during a manufacturing process of the light control member, damage to not only the absorption pattern on the second side surface of anisotropic prism, but also a first side surface, may be effectively prevented in advance by forming an absorptive pattern protective layer material that covers the absorptive pattern material, and dry-etching the absorptive pattern material and the absorptive pattern protective layer material together. Accordingly, the occurrence of defects due to a decrease in optical properties of the light control member that is caused by the damage to the absorptive pattern and the first side surface may be effectively prevented in advance.

### BRIEF DESCRIPTION OF THE DRAWINGS

The above and other features of the disclosure will become more apparent by describing in detail embodiments thereof with reference to the attached drawings, in which:

FIG. 1 is a perspective view of a light control member according to an embodiment;

FIG. 2 is a cross-sectional view of a light control member according to an embodiment;

FIG. 3 is a schematic diagram showing that light is absorbed by the light control member of FIG. 2;

FIG. 4 is a view showing in detail a path of the absorbed light of FIG. 3;

FIG. 5A is an enlarged view of area A of FIG. 2 according to an embodiment;

FIG. 5B is an enlarged view of area A of FIG. 2 according to an alternative embodiment;

FIG. 5C is an enlarged view of area A of FIG. 2 according to another alternative embodiment;

FIG. 6 is an enlarged view of area B of FIG. 2 according to an embodiment;

FIG. 7 is a flowchart showing a method of manufacturing a display device including a light control member according to an embodiment;

FIGS. 8 to 11 are cross-sectional views showing processes of a method of manufacturing a display device including a light control member according to an embodiment;

FIG. 12 is a cross-sectional view of a light control member according to an alternative embodiment;

FIG. 13 is a flowchart showing a method of manufacturing a display device including a light control member according to an alternative embodiment;

FIGS. 14 to 16 are cross-sectional views showing processes of a method of manufacturing a display device including a light control member according to an alternative embodiment;

FIG. 17 is a cross-sectional view of a light control member according to another alternative embodiment;

FIG. 18 is a flowchart showing a method of manufacturing a display device including a light control member according to another alternative embodiment;

FIGS. 19 and 20 are cross-sectional views showing processes of a method of manufacturing a display device including a light control member according to another alternative embodiment;

FIG. 21 is a cross-sectional view of a light control member according to still another alternative embodiment;

FIG. 22 is a cross-sectional view of a light control member according to still another alternative embodiment;

FIG. 23 is a cross-sectional view of a light control member according to still another alternative embodiment;

FIG. 24 is a perspective view of a display device according to an embodiment;

FIG. 25 is a cross-sectional view taken along line I-I′ of FIG. 24;

FIG. 26 is a cross-sectional view of a display device according to an alternative embodiment; and

FIG. 27 is a cross-sectional view of a display device according to another alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

It will be understood that when an element is referred to as being related to another element such as being “coupled” or “connected” to another element, it can be directly coupled or connected to the other element or intervening elements may be therebetween. In contrast, it should be understood that when an element is referred to as being related to another element such as being “directly coupled” or “directly connected” to another element, there are no intervening elements present. Other expressions that explain the relationship between elements, such as “between,” “directly between,” “adjacent to,” or “directly adjacent to,” should be construed in the same way.

Throughout the specification, the same reference numerals will refer to the same or like parts.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the invention will be described in detail with reference to the accompanying drawings.

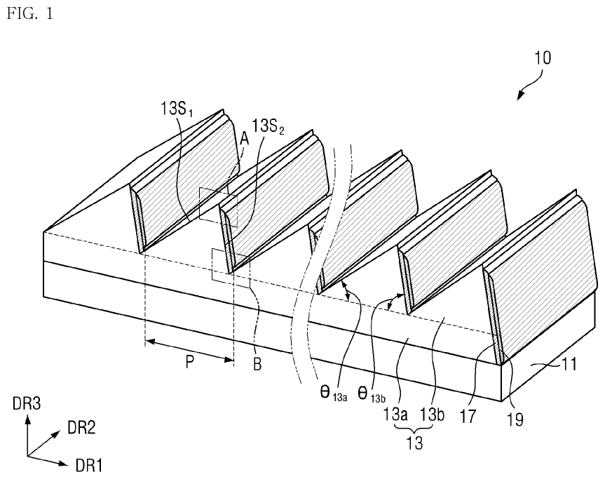

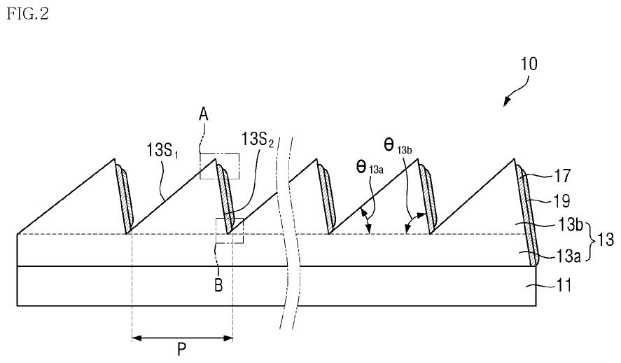

FIG. 1 is a perspective view of a light control member according to an embodiment. FIG. 2 is a cross-sectional view of a light control member according to an embodiment.

An embodiment of a light control member 10 may be included in a display device that displays an image. The display device may be included in various electronic devices such as televisions, laptop computers, monitors, billboards and Internet-of-Things (“IoT”) devices as well as portable electronic devices such as mobile phones, smart phones, tablet personal computers (tablet “PC”s), smart watches, watch phones, mobile communication terminals, electronic notebooks, electronic books, portable multimedia players (“PMP”s), navigation systems and ultra-mobile PCs (“UMPC”s). In the illustrated embodiment, the light control member 10 may be used in a vehicle-mounted display device, but is not limited thereto, and may be applied to other exemplified display devices.

Referring to FIGS. 1 and 2, an embodiment of the light control member 10 may be combined with a display module that displays a screen. The display module includes a display panel that generates an image and outputs the image to an outside. The display panel may be an organic display panel including a self-light emitting organic layer, or an inorganic display panel, e.g., a nano light emitting diode (“LED”) or a micro LED, including a self-light emitting inorganic semiconductor layer. Alternatively, the display panel may be a liquid crystal display panel.

When the light control member 10 is bonded to the display panel, the light control member 10 may be a member that controls a path of light emitted from the display panel.

In one embodiment, for example, when the light emitted from the display panel is in a visible wavelength band, the light control member 10 may be a member that controls a path of light in the visible wavelength band. In one alternative embodiment, for example, when the light emitted from the display panel is in an ultraviolet or infrared wavelength band, the light control member 10 may be a member that controls a path of light in the ultraviolet or infrared wavelength band. In one alternative embodiment, for example, the light control member 10 may be a member that controls a path of light in a wavelength band encompassing the visible light wavelength band and other wavelength bands (such as ultraviolet or infrared).

An embodiment of the light control member 10 may include a light control substrate 11, an anisotropic prism 13 disposed on the light control substrate 11, an absorptive pattern 17 disposed on the anisotropic prism 13, and an absorptive pattern protective layer 19 disposed on the absorptive pattern 17.

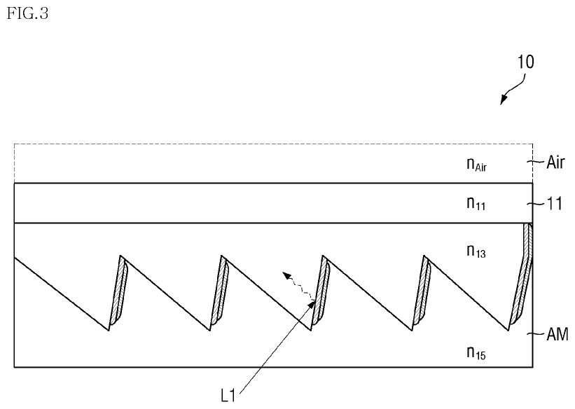

The light control substrate 11 may be a transparent insulating substrate. The light control substrate 11 may include a rigid material such as glass or quartz. In one embodiment, for example, the light control substrate 11 may include a transparent insulating rigid material. A refractive index n₁₁ (see FIG. 3) of the light control substrate 11 may be about 1.5. However, the disclosure is not limited thereto, and the light control substrate 11 may be a flexible substrate including a flexible material such as polyimide (“PI”). In this case, the light control substrate 11 may be bent, twisted, folded, or rolled.

The anisotropic prism 13 may be disposed on the light control substrate 11. The anisotropic prism 13 may be disposed directly on one surface of the light control substrate 11. The anisotropic prism 13 may include a first prism portion 13a disposed directly on one surface of the light control substrate 11, and a plurality of second prism portions 13b disposed on the first prism portion 13a.

In an embodiment, the second prism portions 13b may be arranged in a first direction DR1 and each of the second prism portions 13b may extend in a second direction DR2 crossing the first direction, as shown in FIG. 1. A third direction perpendicular to the first and second directions DR1 and DR2 may be a thickness direction of the light control substrate 11.

The cross-sectional shape of the first prism portion 13a may be a rectangle. In such an embodiment, the top surface of the first prism portion 13a extends along the arrangement direction of the plurality of second prism portions 13b or the first direction DR1, and the side surfaces of the first prism portion 13a may extend along a third direction DR3, i.e., the thickness direction of the light control substrate 11, that crosses the arrangement direction of the plurality of second prism portions 13b.

The second prism portion 13b may have a cross-sectional shape including a first side surface 13S₁ extending at a first angle θ₁₃ₐ with respect to one surface of the light control substrate 11, and a second side surface 13S₂extending at a second angle θ_{13b}, which is greater than the first angle θ₁₃ₐ, with respect to the light control substrate 11. The first angle θ₁₃ₐ and the second angle θ_{13b} may be determined or variously modified based on various designs for controlling the emission angle. In one embodiment, for example, the second angle θ_{13b} may be a right angle or an acute angle, and the first angle θ₁₃ₐ may be an acute angle. The second angle θ_{13b} may be in an angular range of about 80° to about 90°, or may be about 87°. The first angle θ₁₃ₐ may be in an angular range of about 30° to about 80°.

The cross-sectional shape of the second prism portion 13b may be a triangle. In an embodiment, the bottom surface of the second prism portion 13b which is in contact with the first prism portion 13a may form the bottom side of the triangle, and both side surfaces 13S₁ and 13S₂ of the second prism portion 13b may form the remaining two sides of the triangle. When the second angle θ_{13b} is 90°, the cross-sectional shape of the second prism portion 13b may be a right-angled triangle.

The plurality of second prism portions 13b may be arranged along one direction. The cross-sectional shapes of the plurality of second prism portions 13b may all be the same as each other, but are not limited thereto.

The anisotropic prism 13 serves to control a path of light incident on the anisotropic prism 13. More specifically, the anisotropic prism 13 may have a greater refractive index than a medium before light reaches the anisotropic prism 13, thereby serving to change the path of light incident on the anisotropic prism 13 such that the light proceeds in a more vertical direction or the third direction DR3. In one embodiment, for example, a refractive index n₁₃ (see FIG. 3) of the anisotropic prism 13 may be greater than the refractive index n₁₁ of the light control substrate 11.

The anisotropic prism 13 may include an organic insulating material. The anisotropic prism 13 may include, for example, an insulating resin. The first prism portion 13a and the second prism portions 13b may include a same insulating resin as each other. The first prism portion 13a and the second prism portions 13b may be integrally formed with each other as a unitary unit through a same manufacturing process. In one embodiment, for example, the first prism portion 13a and the second prism portions 13b may be formed through an imprint method. However, the disclosure is not limited thereto, and alternatively, the first prism portion 13a may be first formed on one surface of the light control substrate 11, and then, the second prism portions 13b may be sequentially formed on the first prism portion 13a. The boundary between the first prism portion 13a and the second prism portions 13b formed with a time difference may be distinguished by an air layer or the like. However, the disclosure is not limited thereto, and the first prism portion 13a and the second prism portions 13b may be integrally formed with each other without a distinguished boundary as in a case where the first prism portion 13a and the second prism portions 13b are formed at the same time.

The absorptive pattern 17 may be disposed on the second side surface 13S₂ of the anisotropic prism 13. The absorptive pattern 17 may be disposed directly on the second side surface 13S₂ of the second prism portion 13b of the anisotropic prism 13. As in a manufacturing method to be described later, the absorptive pattern 17 may be conformally formed or coated over the entire surfaces 13S₁ and 13S₂ of the anisotropic prism 13 and then dry-etched. At this time, an absorptive pattern material disposed on the first side surface 13S₁ of the anisotropic prism 13 is removed since the absorptive pattern material disposed on the first side surface 13S₁ has a smaller thickness in the thickness direction than an absorptive pattern material disposed on the second side surface 13S₂ of the anisotropic prism 13. However, even after the absorptive pattern material disposed on the first side surface 13S₁ of the anisotropic prism 13 is removed, at least the absorptive pattern material disposed on the second side surface 13S₂ of the anisotropic prism 13 remains to form the absorptive pattern 17 as shown in FIGS. 1 and 2.

The absorptive pattern protective layer 19 may be disposed on the absorptive pattern 17, and on the second side surface 13S₂ of the second prism portion 13b of the anisotropic prism 13. As in the manufacturing method to be described later, an absorptive pattern protective layer material may be formed on the absorptive pattern material and then dry-etched together with the absorptive pattern material. At this time, the absorptive pattern protective layer material disposed on the first side surface 13S₁ of the anisotropic prism 13 is removed since the absorptive pattern protective layer material disposed on the first side surface 13S₁ has a smaller thickness in the thickness direction than the absorptive pattern protective layer material disposed on the second side surface 13S₂ of the anisotropic prism 13. However, even after the absorptive pattern protective layer material disposed on the first side surface 13S₁ of the anisotropic prism 13 is removed, at least the absorptive pattern protective layer material disposed on the second side surface 13S₂ of the anisotropic prism 13 remains to form the absorptive pattern protective layer 19 as shown in FIGS. 1 and 2.

Hereinafter, a light absorption process of an embodiment of the absorptive pattern 17 will be described in greater detail with reference to FIG. 3.

FIG. 3 is a schematic diagram showing that light is absorbed by the light control member of FIG. 2.

Referring to FIG. 3, in an embodiment, an adhesive member AM is disposed in the lower portion of the light control member 10. Since the adhesive member AM is desired to transmit incident light to the light control member 10 without loss, the adhesive member AM may include an optically clear adhesive material. In one embodiment, for example, the adhesive member AM may be an optically clear adhesive (“OCA”) or an optically clear resin (“OCR”), but is not limited thereto.

FIG. 3 shows a refractive index n₁₅ of the adhesive member AM, and the refractive index n₁₃ of the anisotropic prism 13, the refractive index n₁₁ of the light control substrate 11 of the light control member 10, and a refractive index n_{Air} of an air layer. The refractive index n₁₃ of the anisotropic prism 13 may be greater than the refractive index n₁₅ of the adhesive member AM.

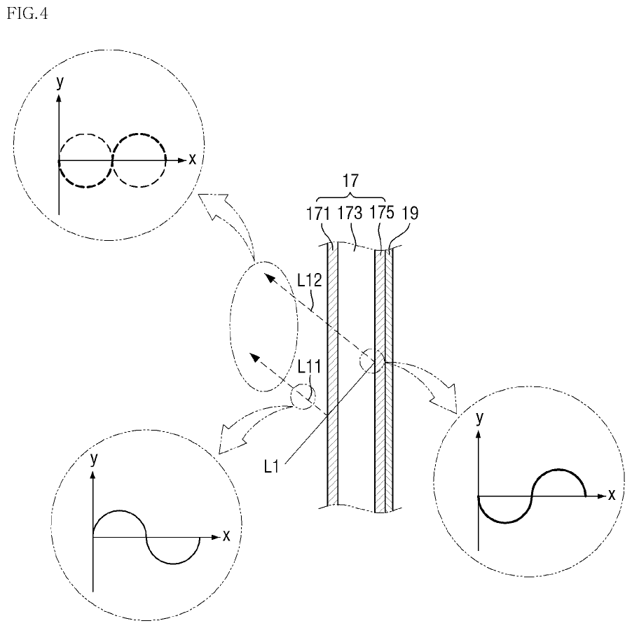

Light L1 transmitted through the adhesive member AM may be incident on the absorptive pattern 17, and then, as described above with reference to FIGS. 1 and 2, may be absorbed through the absorptive pattern 17 and be extinguished. This will hereinafter be described in detail with reference to FIG. 4.

FIG. 4 is a view showing in detail a path of the absorbed light of FIG. 3.

Referring to FIG. 4, the absorptive pattern 17 may include a plurality of layers, and the plurality of layers may include at least one of a metal layer or an insulating layer. The absorptive pattern 17 may include the plurality of layers in which the metal and insulating layers are alternately disposed one on another. In one embodiment, for example, the absorptive pattern 17 may include a first metal layer 171, an insulating layer 173, and a second metal layer 175.

The light L1 incident toward the absorptive pattern 17 may be reflected from the first metal layer 171 (L11) or may pass through the first metal layer 171 and the insulating layer 173 and be reflected from the second metal layer 175 (L12). The distance between the first metal layer 171 and the second metal layer 175, i.e., the width or thickness of the insulating layer 173 may be set in consideration of a path difference of a destructive interference condition between the light that has been reflected directly from the first metal layer 171 and the light that has been reflected from the second metal layer 175 after passing through the first metal layer 171 and the insulating layer 173.

When the width or thickness of the insulating layer 173 is set in consideration of a path difference of a destructive interference condition between the light that has been reflected directly from the first metal layer 171 (L11) and the light that has been reflected from the second metal layer 175 (L12) after passing through the first metal layer 171 and the insulating layer 173, for example, the amplitude (y-axis) over time (x-axis) of the light that has been reflected directly from the first metal layer 171 may be equal in size but opposite in sign to the amplitude (y-axis) over time (x-axis) of the light that has been reflected from the second metal layer 175 after passing through the first metal layer 171 and the insulating layer 173. That is, the light reflected directly from the first metal layer 171 and the light reflected from the second metal layer 175 after passing through the first metal layer 171 and the insulating layer 173 may cancel each other to be absorbed.

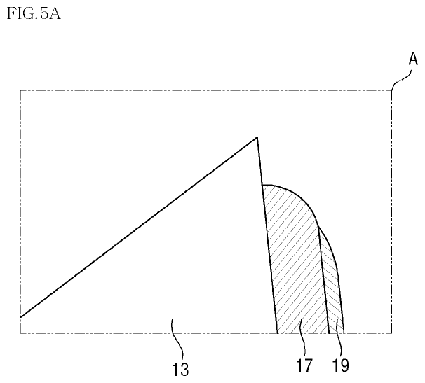

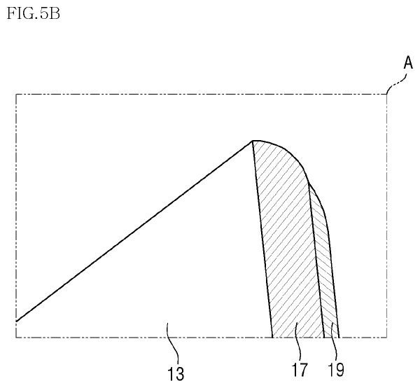

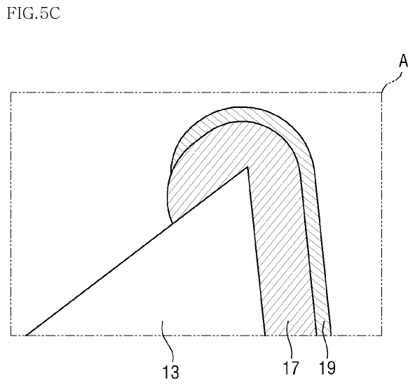

The absorptive pattern 17 and the absorptive pattern protective layer 19 will hereinafter be described in greater detail with reference to FIG. 5A.

FIG. 5A is an enlarged view of area A of FIG. 2 according to an embodiment.

Referring to FIG. 5A, an embodiment of the absorptive pattern 17 may expose a partial region of the anisotropic prism 13 from the upper end (or apex) of the anisotropic prism 13.

The absorptive pattern 17 may be disposed on each of the second side surfaces 13S₂ of the second prism portions 13b of the anisotropic prism 13. The absorptive pattern 17 may serve to control a path of light by absorbing light incident on the absorptive pattern 17 as a part of light incident on the light control member 10.

The absorptive pattern 17 may be disposed on each of the second side surfaces 13S₂ of the second prism portions 13b, and the adjacent absorptive patterns 17 may be repeatedly arranged with a constant pitch P. The thickness of the absorptive pattern 17 may be substantially the same for each area. In one embodiment, for example, the absorptive pattern 17 may have a thickness distribution of about 10% or less for each area.

In an embodiment, the absorptive pattern 17 may have a thickness distribution of about 10% or more. In such an embodiment, as long as the absorptive pattern 17 is repeatedly arranged with a constant pitch P, the absorptive pattern 17 may absorb light beyond a set range of the viewing angle, and thus may absorbing the light incident on the absorptive pattern 17.

The absorptive pattern protective layer 19 may be disposed on the absorptive pattern 17. Similarly to the absorptive pattern 17, the absorptive pattern protective layer 19 is disposed on each of the second side surfaces 13S₂ of the second prism portions 13b, and the adjacent absorptive pattern protective layers 19 may be repeatedly arranged with a constant pitch P. In an embodiment, as shown in FIG. 5A, the absorptive pattern protective layer 19 may expose a partial region of the anisotropic prism 13 from the upper end (or apex) of the anisotropic prism 13.

During the dry etching of the absorptive pattern 17, the absorptive pattern protective layer 19 may serve to prevent, in advance, the anisotropic prism 13 under the absorptive pattern 17 from being over-etched by an etching gas or the like and being physically damaged.

The absorptive pattern protective layer 19 may include an inorganic insulating material. In one embodiment, for example, the inorganic insulating material of the absorptive pattern protective layer 19 may include silicon oxide, aluminum oxide, silicon nitride, or the like, but is not limited thereto.

FIG. 5B is an enlarged view of area A of FIG. 2 according to an alternative embodiment, and FIG. 5C is an enlarged view of area A of FIG. 2 according to another alternative embodiment.

In an alternative embodiment, as shown in FIG. 5B, the absorptive pattern 17 may extend to the end (or apex) of the second side surface 13S₂ (see FIG. 2) of the second prism portion 13b of the anisotropic prism 13 without exposing the second side surface 1352. In another alternative embodiment, as shown in FIG. 5C, the absorptive pattern 17 may completely cover the second side surface 13S₂ of the second prism portion 13b of the anisotropic prism 130, and may partially cover the first side surface 13S₁ (see FIG. 2) thereof.

In such an embodiment, the absorptive pattern 17 may include a plurality of layers.

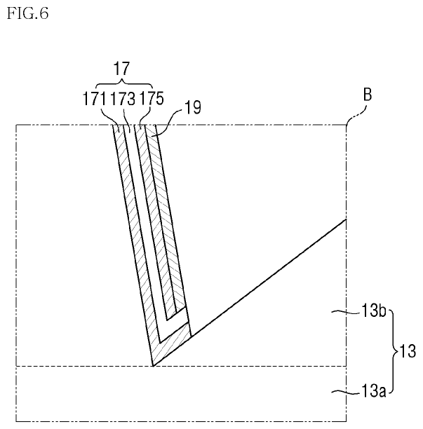

Hereinafter, the absorptive pattern 17 will be described in greater detail with reference to FIG. 6.

FIG. 6 is an enlarged view of area B of FIG. 2 according to an embodiment.

Referring to FIG. 6, in an embodiment, the absorptive pattern 17 may include a plurality of layers, and the plurality of layers may have at least one of a metal layer or an insulating layer. The absorptive pattern 17 may include the plurality of layers in which the metal and insulating layers are alternately disposed one on another.

In an embodiment, as shown in FIG. 6, the absorptive pattern 17 may include the first metal layer 171 disposed directly on the second side 13S₂ of the second prism portion 13b, the insulating layer 173 disposed directly on the first metal layer 171, and the second metal layer 175 disposed directly on the insulating layer 173, but is not limited thereto.

The metal layers 171 and 175 may include at least one selected from cobalt (Co), tantalum (Ta), and aluminum (Al). The first metal layer 171 and the second metal layer 175 may include a same material as each other. In one embodiment, for example, the first metal layer 171 and the second metal layer 175 may each include tantalum (Ta), but are not limited thereto.

The insulating layer 173 may include an inorganic insulating material. In one embodiment, for example, the inorganic insulating material of the insulating layer 173 may include at least one selected from silicon oxide, aluminum oxide, and silicon nitride, but is not limited thereto.

With reference to FIG. 6 together with FIG. 2, the first metal layer 171 may be disposed directly on the second side surface 13S₂ and the first side surface 13S₁ of the second prism portion 13b. The first metal layer 171 disposed directly on the first side surface 13S₁ may be aligned with the absorptive pattern protective layer 19 in the thickness direction.

The insulating layer 173 may also be disposed on the first metal layer 171 disposed directly on the second side surface 13S₂ and the first side surface 13S₁ of the second prism portion 13b.

The insulating layer 173 disposed above the first side surface 13s1 may be aligned with the absorptive pattern protective layer 19 in the thickness direction. The end of the insulating layer 173 may be aligned with the end of the first metal layer 171 in the thickness direction.

In a manufacturing process of the light control member 10 according to an embodiment, damages to not only the absorption pattern 17 on the second side surface 13S₂ of the second prism portion 13b of the anisotropic prism 13, but also the first side surface 13S₁ of the second prism portion 13b, may be effectively prevented in advance by forming an absorptive pattern protective layer material that covers the absorptive pattern material, and dry-etching the absorptive pattern material and the absorptive pattern protective layer material together. Accordingly, the occurrence of defects due to a decrease in optical properties of the light control member 10 that is caused by the damage to the absorptive pattern 17 and the first side surface 13S₁, and a decrease in yield may be effectively prevented in advance.

Hereinafter, a method of manufacturing a display device including a light control member according to an embodiment will be described. In such an embodiment, the same components as those of the above-described embodiment are denoted by the same reference numerals, and any repetitive detailed description thereof will be omitted or simplified.

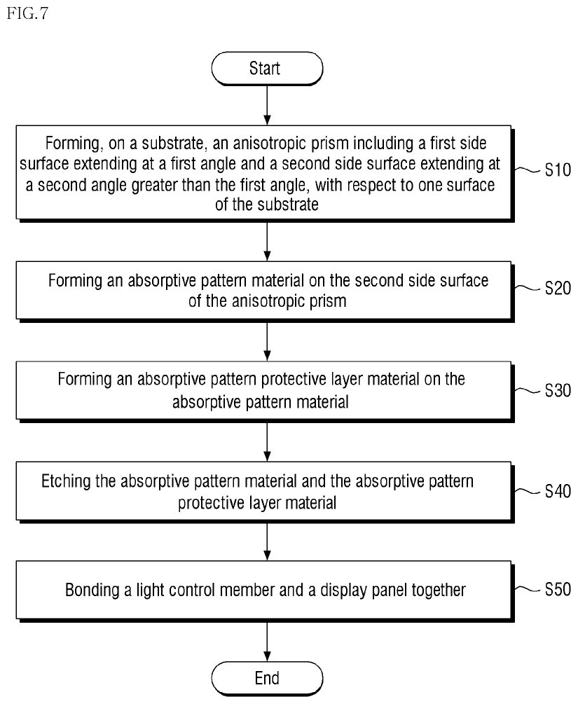

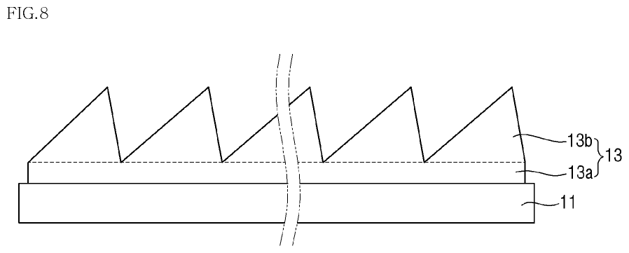

FIG. 7 is a flowchart showing a method of manufacturing a display device including a light control member according to an embodiment. FIGS. 8 to 11 are cross-sectional views showing processes of a method of manufacturing a display device including a light control member according to an embodiment.

In an embodiment, referring to FIG. 2 along with FIGS. 7 and 8, the anisotropic prism 13 including the first side surface 13S₁ extending at the first angle θ₁₃ₐ with respect to one surface of the light control substrate 11, and the second side surface 13S₂ extending at the second angle θ_{13b}, which is greater than the first angle θ₁₃ₐ, with respect to the one surface of the light control substrate 11 is provided or formed on the light control substrate 11 (S10).

The configuration, shape, function, and material of the anisotropic prism 13 may be the same as those described above, and thus any repetitive detailed description thereof will be omitted.

The anisotropic prism 13 serves to control a path of light incident on the anisotropic prism 13. In an embodiment, the anisotropic prism 13 may have a greater refractive index than a medium before light reaches the anisotropic prism 13, thereby serving to change the path of light incident on the anisotropic prism 13 such that the light proceeds in a more vertical direction.

The anisotropic prism 13 may include an organic insulating material. The anisotropic prism 13 may include, for example, an insulating resin. The first prism portion 13a and the second prism portion 13b may include a same insulating resin as each other. The first prism portion 13a and the second prism portion 13b may be integrally formed with each other as a single unitary unit at the same time through a same manufacturing process. In one embodiment, for example, the first prism portion 13a and the second prism portion 13b may be formed through an imprint method. However, the disclosure is not limited thereto, and the first prism portion 13a may be first formed on one surface of the light control substrate 11, and then, the second prism portions 13b may be sequentially formed on the first prism portion 13a. The boundary between the first prism portion 13a and the second prism portions 13b formed with a time difference may be distinguished by an air layer or the like. However, the disclosure is not limited thereto, and the first prism portion 13a and the second prism portions 13b may be formed integrally with each other without a distinguished boundary therebetween.

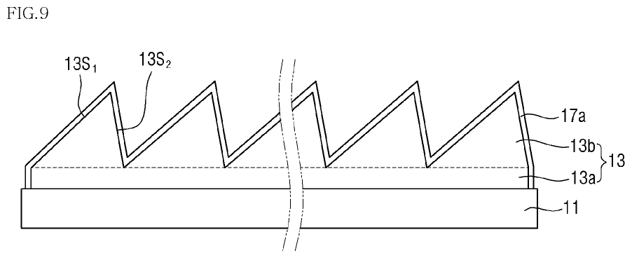

Subsequently, referring to FIGS. 7 and 9, an absorptive pattern material 17a is provided or formed on the anisotropic prism 13 (S20).

The absorptive pattern material 17a may be provided or formed on the first side surface 13S₁ and the second side surface 13S₂ of the anisotropic prism 13.

The process of forming the absorptive pattern material 17a on the first side surface 13S₁ and the second side surface 13S₂ of the anisotropic prism 13 may be performed by atomic layer deposition (“ALD”). In such an embodiment where the absorptive pattern material 17a is formed in the above manner, the absorptive pattern material 17a may be formed to have a substantially uniform thickness over the surface of the anisotropic prism 13 and may conformally reflect the surface of the anisotropic prism 13.

The absorptive pattern material 17a may include the material of the first metal layer 171, the material of the insulating layer 173, and the material of the second metal layer 175 described above with reference to FIG. 6. The material of the first metal layer 171, the material of the insulating layer 173, and the material of the second metal layer 175 may be stacked one on another.

In an embodiment, the material of the metal layers 171 and 175 may be formed by a vapor deposition method or a sputtering method.

The material of the metal layers 171 and 173 may include at least one selected from cobalt (Co), tantalum (Ta), and aluminum (Al). The material of the first metal layer 171 and the material of the second metal layer 175 may be the same as each other. In one embodiment, for example, the material of the first metal layer 171 and the material of the second metal layer 175 may each include tantalum (Ta), but are not limited thereto.

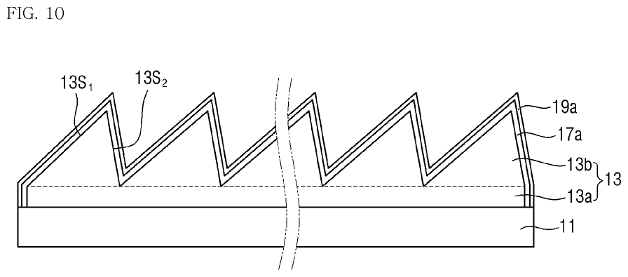

Next, referring to FIGS. 7 and 10, an absorptive pattern protective layer material 19a is provided or formed on the absorptive pattern material 17a (S30).

The absorptive pattern protective layer material 19a may be formed on the first side surface 13S₁ and the second side surface 13S₂ of the anisotropic prism 13.

The absorptive pattern protective layer material 19a may include an inorganic insulating material. In one embodiment, for example, the inorganic insulating material of the absorptive pattern protective layer material 19a may include at least one selected from silicon oxide, aluminum oxide and silicon nitride, for example, but is not limited thereto.

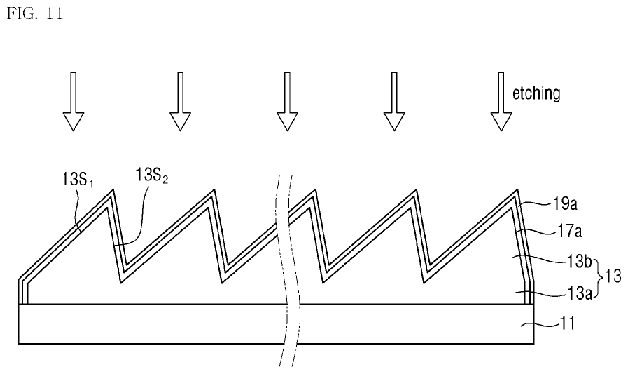

Next, referring to FIGS. 7 and 11, the absorptive pattern material 17a and the absorptive pattern protective layer material 19a are etched (S40).

The process of etching the absorptive pattern material 17a and the absorptive pattern protective layer material 19a may include performing a dry etching. The dry etching may be performed using an etching gas such as chlorine (Cl₂) and fluorine (F₂).

The etching process of the absorptive pattern material 17a and the absorptive pattern protective layer material 19a may remove the absorptive pattern material 17a and the absorptive pattern protective layer material 19a on the first side surface 13S₁ of the anisotropic prism 13, and may leave the absorptive pattern material 17a and the absorptive pattern protective layer material 19a on the second side surface 13S₂ of the anisotropic prism 13.

Next, the light control member 10 and a display panel are bonded together or to each other (S50).

In an embodiment, the display panel may be an organic display panel including a self-light emitting organic layer, or an inorganic display panel, e.g., a nano LED or a micro LED, including a self-light emitting inorganic semiconductor layer. In an alternative embodiment, the display panel may be a liquid crystal display panel.

The light control member 10 and the display panel may be bonded with each other through a bonding member or an optically clear adhesive member. The optically clear adhesive member may include an OCA or an OCR, but is not limited thereto.

In a manufacturing process of the light control member 10 according to an embodiment, damage to not only the absorption pattern 17 on the second side surface 13S₂ of the second prism portion 13b of the anisotropic prism 13, but also the first side surface 13S₁ of the second prism portion 13b, it may be effectively prevented in advance by forming an absorptive pattern protective layer material that covers the absorptive pattern material, and dry-etching the absorptive pattern material and the absorptive pattern protective layer material together. Accordingly, the occurrence of defects due to a decrease in optical properties of the light control member 10 that is caused by the damage to the absorptive pattern 17 and the first side surface 13S₁, and a decrease in yield may be effectively prevented in advance.

Hereinafter, a light control member according to an alternative embodiment will be described. In such an embodiment, the same components as those of the above-described embodiment are denoted by the same reference numerals, and any repetitive detailed description thereof will be omitted or simplified.

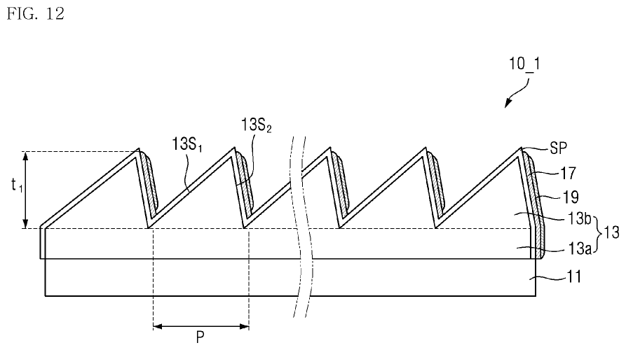

FIG. 12 is a cross-sectional view of a light control member according to an alternative embodiment.

The light control member 10_1 shown in FIG. 12 is substantially the same as the light control member 10 of FIG. 2 except that an etching stopper SP is further included on the first side surface 13S₁ and the second side surface 13S₂ of the anisotropic prism 13.

In such an embodiment, the light control member 10_ may further include the etching stopper SP on the first side surface 13S₁ and the second side surface 13S₂ of the anisotropic prism 13.

The etching stopper SP may cover the first side surface 13S₁ and the second side surface 13S₂ of the anisotropic prism 13.

The etching stopper SP may be disposed directly on the first side surface 13S₁ and may be disposed between the second side surface 13S₂ and the absorptive pattern 17. The etching stopper SP may be disposed directly on the second side surface 13S₂.

The etching stopper SP may be integrally formed as a single unitary unit on the entire surface of the anisotropic prism 13. The etching stopper SP may be disposed on the first side surface 13S₁, the second side surface 13S₂, and both side surfaces of the first prism portion 13a of the anisotropic prism 13 to cover the entire surface of the anisotropic prism 13. In such an embodiment, where the etching stopper SP covers the entire surface of the anisotropic prism 13, when forming the absorptive pattern 17 and the absorptive pattern protective layer 19 on the second side surface 13S₂ of the anisotropic prism 13 by dry etching or the like, which will be described later, the etching stopper SP may serve to prevent damage to the surface of the anisotropic prism 13 due to over-etching. In such an embodiment, an etching rate of the etching stopper SP with respect to the etching gas of the dry etching is lower than an etching rate of the absorptive pattern 17 with respect to the etching gas of the dry etching and an etching rate of the absorptive pattern protective layer 19 with respect to the etching gas of the dry etching. In such an embodiment, as selectivity, which is a difference between the etching rates, increases, the protection function of the etching stopper SP for the surface of the anisotropic prism 13 may be further improved.

The etching stopper SP may include a dielectric material. In one embodiment, for example, the etching stopper SP may include at least one selected from indium tin oxide (“ITO”), ZrOx, HfOx, and Al₂O₃, which has a lower etching rate with respect to the etching gas used in the etching of the absorptive pattern 17 than the absorptive pattern material 17a.

The etching stopper SP may be formed on the surface of the anisotropic prism 13 by ALD. When the etching stopper SP is provided or formed on the surface of the anisotropic prism 13 by the above method, the etching stopper SP may not only reflect the shape of the surface of the anisotropic prism 13 conformally, but also may have a same thickness for each area. When the etching stopper SP positioned on a light path has the same thickness, the path of light incident through the light control member 10 may be effectively controlled.

Hereinafter, a method of manufacturing a display device including a light control member according to an alternative embodiment will be described. In such an embodiment, the same components as those of the above-described embodiment are denoted by the same reference numerals, and any repetitive detailed description thereof will be omitted or simplified.

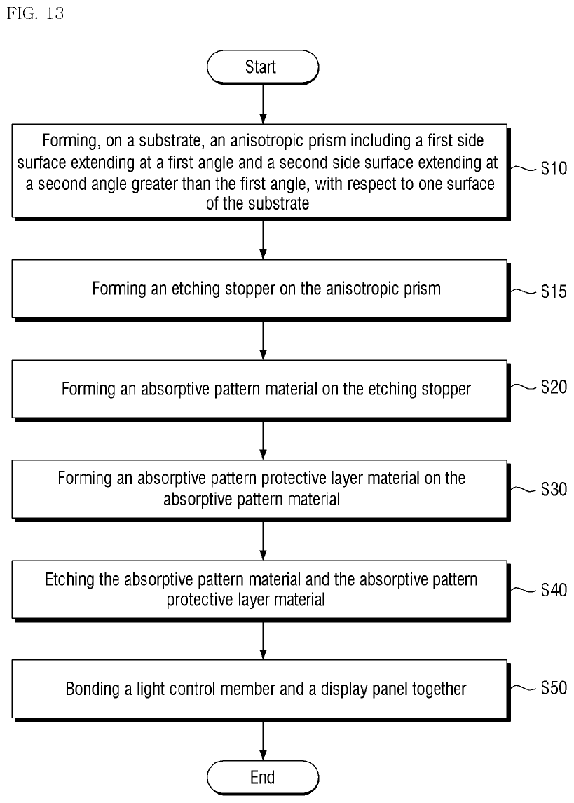

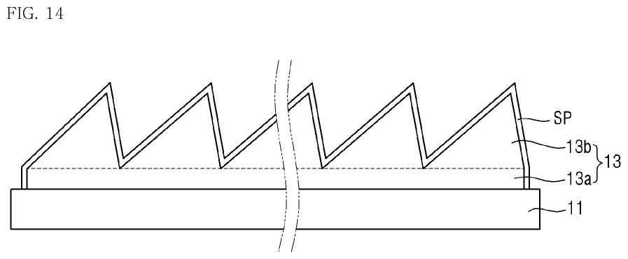

FIG. 13 is a flowchart showing a method of manufacturing a display device including a light control member according to an alternative embodiment. FIGS. 14 to 16 are cross-sectional views showing processes of a method of manufacturing a display device including a light control member according to another embodiment.

Referring to FIGS. 13 and 14, the anisotropic prism 13 including the first side surface 13S₁ extending at the first angle θ₁₃ₐ with respect to one surface of the light control substrate 11, and the second side surface 13S₂ extending at the second angle θ_{13b}, which is greater than the first angle θ₁₃ₐ, with respect to the one surface of the light control substrate 11 is provided or formed on the light control substrate 11 (S10).

The configuration, shape, function, and material of the anisotropic prism 13 are the same as those described above, and thus any repetitive detailed description thereof will be omitted.

Subsequently, the etching stopper SP is provided or formed on the anisotropic prism 13 (S15).

The etching stopper SP may be formed on the surface of the anisotropic prism 13 by ALD.

The etching stopper SP may include at least one selected from ITO, ZrOx, HfOx, and Al₂O₃, which has a lower etching rate with respect to the etching gas used in the etching of the absorptive pattern material 17a than the absorptive pattern material 17a.

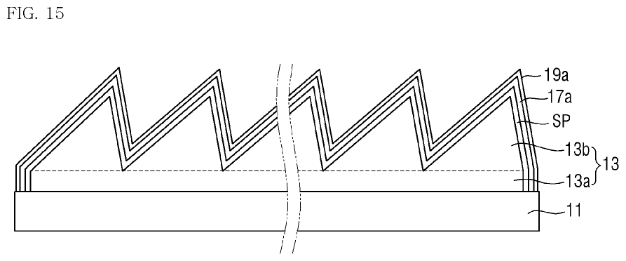

Next, referring to FIGS. 13 and 15, the absorptive pattern material 17a is provided or formed on the etching stopper SP (S20).

The absorptive pattern material 17a may be formed on the first side surface 13S₁ and the second side surface 13S₂ of the anisotropic prism 13.

The absorptive pattern material 17a may include the material of the first metal layer 171, the material of the insulating layer 173, and the material of the second metal layer 175 described above with reference to FIG. 6. The material of the first metal layer 171, the material of the insulating layer 173, and the material of the second metal layer 175 may be stacked one on another.

The material of the metal layers 171 and 173 may include at least one selected from cobalt (Co), tantalum (Ta), and aluminum (Al). The material of the first metal layer 171 and the material of the second metal layer 175 may include a same material as each other. In one embodiment, for example, the material of the first metal layer 171 and the material of the second metal layer 175 may each include tantalum (Ta), but are not limited thereto.

Next, referring to FIGS. 13 and 15, the absorptive pattern protective layer material 19a is provided or formed on the absorptive pattern material 17a (S30).

The absorptive pattern protective layer material 19a may be formed on the first side surface 13S₁ and the second side surface 13S₂ of the anisotropic prism 13.

The absorptive pattern protective layer material 19a may include an inorganic insulating material. In one embodiment, for example, the inorganic insulating material of the absorptive pattern protective layer material 19a may include at least one selected from silicon oxide, aluminum oxide and silicon nitride, for example, but is not limited thereto.

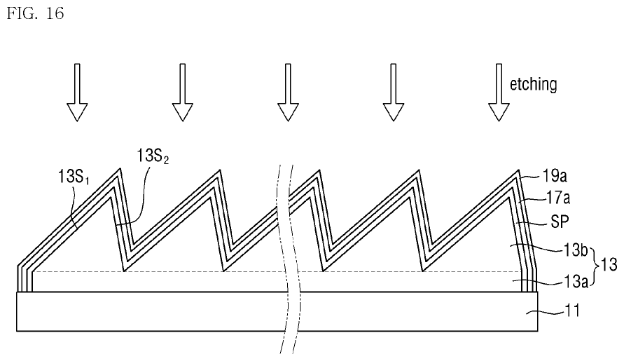

Next, referring to FIGS. 13 and 16, the absorptive pattern material 17a and the absorptive pattern protective layer material 19a are etched (S40).

The process of etching the absorptive pattern material 17a and the absorptive pattern protective layer material 19a may include performing a dry etching. The dry etching may be performed using an etching gas such as chlorine (Cl₂) and fluorine (F₂).

The etching process of the absorptive pattern material 17a and the absorptive pattern protective layer material 19a may remove the absorptive pattern material 17a and the absorptive pattern protective layer material 19a on the first side surface 13S₁ of the anisotropic prism 13, and may leave the absorptive pattern material 17a and the absorptive pattern protective layer material 19a on the second side surface 13S₂ of the anisotropic prism 13.

Next, the light control member 10 and the display panel are bonded together or to each other (S50).

In an embodiment, the display panel may be an organic display panel including a self-light emitting organic layer, or an inorganic display panel, e.g., a nano LED or a micro LED, including a self-light emitting inorganic semiconductor layer. In an alternative embodiment, the display panel may be a liquid crystal display panel.

The light control member 10 and the display panel may be bonded with each other through a bonding member or an optically clear adhesive member. The optically clear adhesive member may include an OCA or an OCR, but is not limited thereto.

In a manufacturing process of the light control member 10 according to an embodiment, damage to not only the absorption pattern 17 on the second side surface 13S₂ of the second prism portion 13b of the anisotropic prism 13, but also the first side surface 13S₁ of the second prism portion 13b, it may be effectively prevented in advance by forming an absorptive pattern protective layer material that covers the absorptive pattern material, and dry-etching the absorptive pattern material and the absorptive pattern protective layer material together. Accordingly, the occurrence of defects due to a decrease in optical properties of the light control member 10 that is caused by the damage to the absorptive pattern 17 and the first side surface 13S₁, and a decrease in yield may be effectively prevented in advance.

In such an embodiment, since the etching stopper SP covers the entire surface of the anisotropic prism 13, when forming the absorptive pattern 17 and the absorptive pattern protective layer 19 on the second side surface 13S₂ of the anisotropic prism 13 by dry etching and the like, the etching stopper SP may serve to prevent damage to the surface of the anisotropic prism 13 due to over-etching.

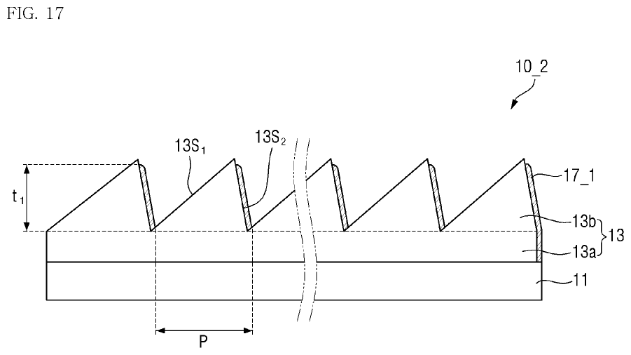

FIG. 17 is a cross-sectional view of a light control member according to another alternative embodiment.

The light control member 10_2 shown in FIG. 17 is substantially the same as the light control member 10 of FIG. 1 except that the absorptive pattern 17_1 is formed of only a metal layer.

In such an embodiment, the light control member 10_2 may include only the metal layer as the absorptive pattern 17_1.

The absorptive pattern 17_1 may include at least one selected from cobalt (Co), tantalum (Ta), and aluminum (Al).

The thickness of the absorptive pattern 17_1 may be substantially the same for each area. In one embodiment, for example, the absorptive pattern 17_1 may have a thickness distribution of about 10% or less for each area.

The absorptive pattern 17_1 may be formed of a single metal layer.

According to an embodiment, since the absorptive pattern 17_1 is formed of a single metal layer, the film thickness distribution may be reduced. In such an embodiment, the thickness of the absorptive pattern 17_1 may be substantially the same for each area. In one embodiment, for example, the absorptive pattern 17_1 may have a thickness distribution of about 10% or less for each area.

In such an embodiment, since the absorptive pattern 17_1 is formed of a single metal layer, the deposition time may be reduced.

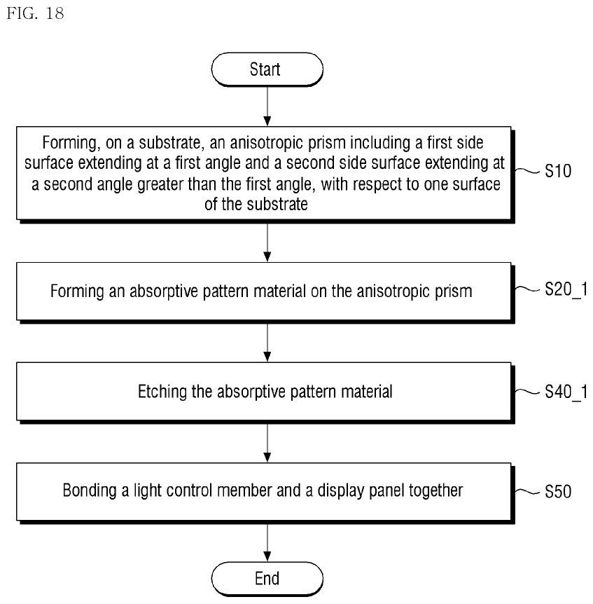

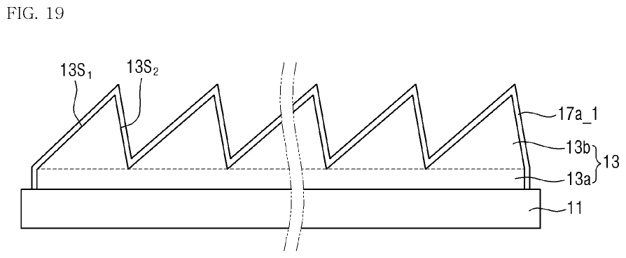

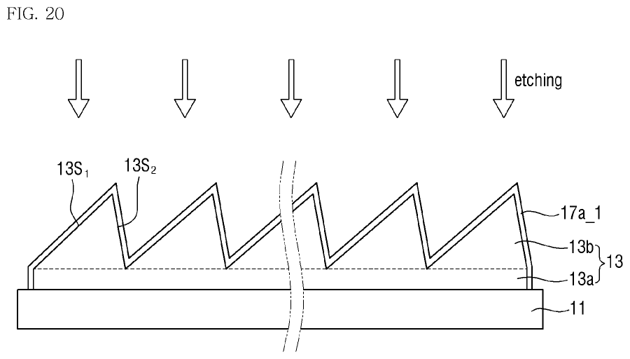

FIG. 18 is a flowchart showing a method of manufacturing a display device including a light control member according to still another alternative embodiment. FIGS. 19 and 20 are cross-sectional views showing the steps of a method of manufacturing a display device including a light control member according to still another alternative embodiment.

In such an embodiment, referring to FIGS. 18 and 19, the anisotropic prism 13 including the first side surface 13S₁ extending at the first angle θ₁₃ₐ with respect to one surface of the light control substrate 11, and the second side surface 13S₂ extending at the second angle θ_{13b}, which is greater than the first angle θ₁₃ₐ, with respect to the one surface of the light control substrate 11 is provided or formed on the light control substrate 11 (S10).

The configuration, shape, function, and material of the anisotropic prism 13 are the same as those described above, and thus any repetitive detailed description thereof will be omitted.

The anisotropic prism 13 serves to control a path of light incident on the anisotropic prism 13. In an embodiment, the anisotropic prism 13 may have a greater refractive index than a medium before light reaches the anisotropic prism 13, thereby serving to change the path of light incident on the anisotropic prism 13 such that the light proceeds in a more vertical direction.

The anisotropic prism 13 may include an organic insulating material. The anisotropic prism 13 may include, for example, an insulating resin. The first prism portion 13a and the second prism portion 13b may include a same insulating resin as each other. The first prism portion 13a and the second prism portion 13b may be integrally formed with each other as a unitary unit at the same time through a same manufacturing process. In one embodiment, for example, the first prism portion 13a and the second prism portion 13b may be formed through an imprint method. However, the disclosure is not limited thereto, and the first prism portion 13a may be first formed on one surface of the light control substrate 11, and then, the second prism portions 13b may be sequentially formed on the first prism portion 13a. The boundary between the first prism portion 13a and the second prism portions 13b formed with a time difference may be distinguished by an air layer or the like. However, the disclosure is not limited thereto, and the first prism portion 13a and the second prism portions 13b may be formed integrally without a distinguished boundary therebetween.

Subsequently, referring to FIGS. 18 and 19, an absorptive pattern material 17a_1 is provided or formed on the anisotropic prism 13 (S20_1).

The absorptive pattern material 17a_1 may be provided or formed on the first side surface 13S₁ and the second side surface 13S₂ of the anisotropic prism 13.

The process of forming the absorptive pattern material 17a_1 on the first side surface 13S₁ and the second side surface 13S₂ of the anisotropic prism 13 may be performed by ALD. In such an embodiment where the absorptive pattern material 17a_1 is formed in the above manner, the absorptive pattern material 17a_1 may be formed to have a substantially uniform thickness over the surface of the anisotropic prism 13 and may conformally reflect the surface of the anisotropic prism 13.

According to an embodiment, since the anisotropic prism 13 is inclined (refer to the description of FIG. 2), when an absorptive pattern material 17a_1 is formed on the first side surface 13S₁ and the second side surface 13S₂ of the anisotropic prism 130, the absorptive pattern material 17a_1 may be uniformly deposited in a desired direction (which is called directional deposition).

The absorptive pattern material 17a_1 may be formed of only a metal layer.

The absorptive pattern material 17a_1 may include at least one selected from cobalt (Co), tantalum (Ta), and aluminum (Al).

The thickness of the absorptive pattern material 17a_1 may be substantially the same for each area. In one embodiment, for example, the absorptive pattern material 17a_1 may have a thickness distribution of about 10% or less for each area.

The absorptive pattern material 17a_1 may be formed of a single metal layer.

Subsequently, referring to FIGS. 18 and 20, the absorptive pattern material 17a_1 is etched (S40_1)

The process of etching the absorptive pattern material 17a_1 may include performing a dry etching. The dry etching may be performed using an etching gas such as chlorine (Cl₂) and fluorine (F₂).

The etching of the absorptive pattern material 17a_1 may remove the absorptive pattern material 17a_1 on the first side surface 13S₁ of the anisotropic prism 13, and leave the absorptive pattern material 17a_1 on the second side surface 13S₂ of the anisotropic prism 13.

Next, the light control member 10 and the display panel are bonded together or to each other(S50).

In an embodiment, the display panel may be an organic display panel including a self-light emitting organic layer, or an inorganic display panel, e.g., a nano LED or a micro LED, including a self-light emitting inorganic semiconductor layer. In an alternative embodiment, the display panel may be a liquid crystal display panel.

The light control member 10 and the display panel may be bonded with each other through a bonding member or an optically clear adhesive member. The optically clear adhesive member may include an OCA or an OCR, but is not limited thereto.

According to an embodiment, since the absorptive pattern 17_1 is formed of a single metal layer, the film thickness distribution may be reduced. In such an embodiment, the thickness of the absorptive pattern 17_1 may be substantially the same for each area. In one embodiment, for example, the absorptive pattern 17_1 may have a thickness distribution of about 10% or less for each area.

In such an embodiment, since the absorptive pattern 17_1 is formed of a single metal layer, the deposition time may be reduced.

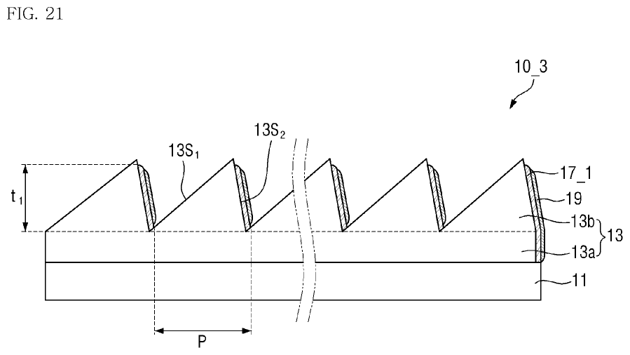

FIG. 21 is a cross-sectional view of a light control member according to still another alternative embodiment.

The light control member 10_3 shown in FIG. 21 is substantially the same as the light control member 10_2 of FIG. 17 except that the absorptive pattern protective layer 19 is further included on the absorptive pattern 17_1.

In such an embodiment, the light control member 10_3 may further include the absorptive pattern protective layer 19 on the absorptive pattern 17_1.

The absorptive pattern 17_1 may be disposed between the absorptive pattern protective layer 19 and the second side surface 13S₂.

In such an embodiment, other elements are substantially the same as those described above, and thus, any repetitive detailed description thereof will be omitted.

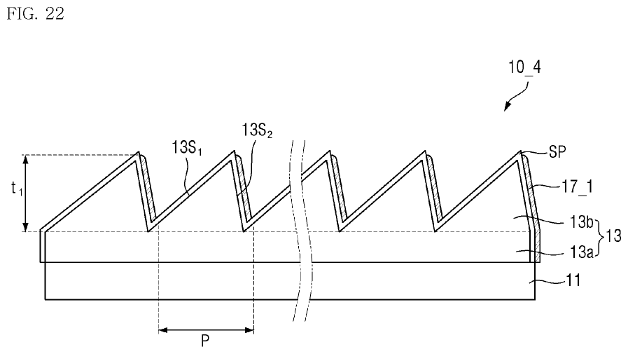

FIG. 22 is a cross-sectional view of a light control member according to still another alternative embodiment.

The light control member 10_4 shown in FIG. 22 is substantially the same as the light control member 10_2 of FIG. 17 except that the etching stopper SP is further included.

In such an embodiment, the light control member 10_4 may further include the etching stopper SP.

The etching stopper SP may be disposed directly on the first side surface 13S land the second side surface 13S₂. The etching stopper SP may be disposed on the second side surface 13S₂ between the anisotropic prism 13 and the absorptive pattern 17_1.

In such an embodiment, other elements are substantially the same as those described above, and thus, any repetitive detailed description thereof will be omitted.

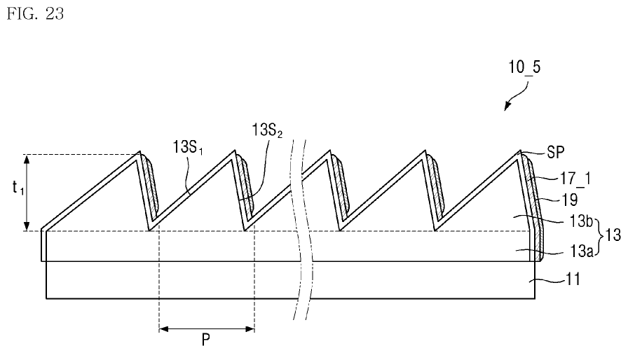

FIG. 23 is a cross-sectional view of a light control member according to still another alternative embodiment.

The light control member 10_5 shown in FIG. 23 is substantially the same as the light control member 10_3 of FIG. 21 except that the etching stopper SP is further included.

In such an embodiment, the light control member 10_5 may further include the etching stopper SP.

In such an embodiment, other elements are substantially the same as those described above, and thus, any repetitive detailed description thereof will be omitted.

Hereinafter, a display device including a light control member according to an embodiment will be described. In such an embodiment, the same components as those of the above-described embodiment are denoted by the same reference numerals, and any repetitive detail description thereof will be omitted or simplified.

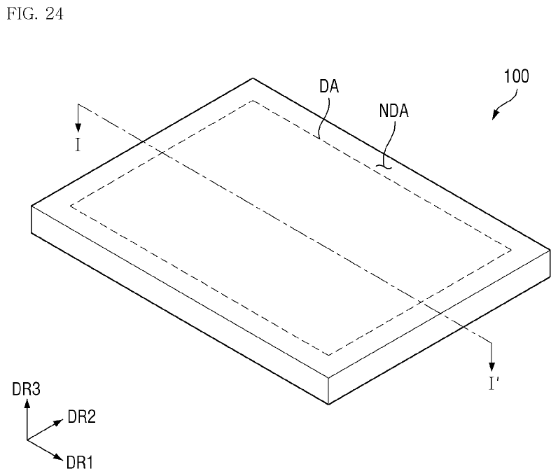

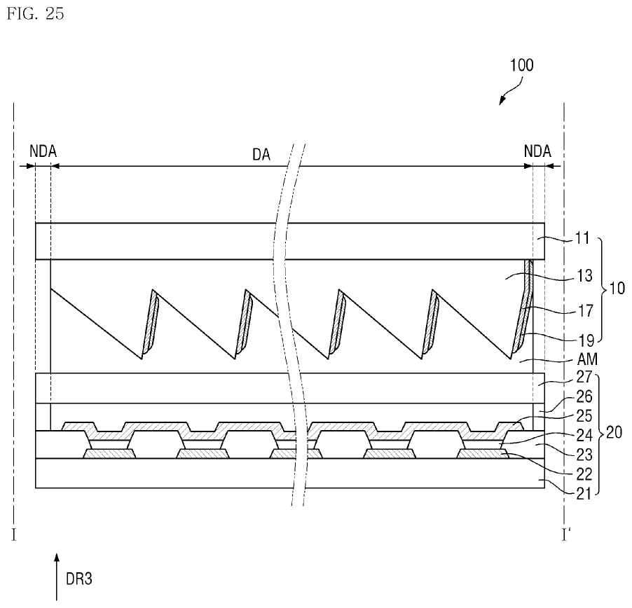

FIG. 24 is a perspective view of a display device according to an embodiment. FIG. 25 is a cross-sectional view taken along line I-I′ of FIG. 24.

Referring to FIGS. 24 and 25, an embodiment of a display device 100 may include a light control member 10′. In such an embodiment, the display device 100 may further include a display module 20 and a bonding member 30 disposed between the display module 20 and the light control member 10′ to bond the display module 20 with the light control member 10′.

The light control member 10′ may have substantially the same configuration as the light control member 10 described above with reference to FIG. 2. Alternatively, the light control member 10′ may be substantially the same as one of the above-described embodiments of the light control member 10_1, 10_2, 10_3, and 10_4.

In such an embodiment, the first direction DR1 and the second direction DR2 cross each other in different directions. In the perspective view of FIG. 24, for simplicity of description, the first direction DR1 which is a horizontal direction of the display device 100 and the second direction DR2 which is a vertical direction of the display device 100 are defined. It would be understood, however, that a direction mentioned in the embodiment refers to a relative direction and the embodiment is not limited to the direction mentioned.

In an embodiment, the display device 100 may be an organic light emitting display device including an organic display panel having a self-light emitting organic layer.

The display device 100 may include a display area DA displaying an image and a non-display area NDA disposed around the display area DA. The display area DA may include a plurality of pixels.

The planar shape of the display device 100 may be a rectangle, but is not limited thereto, and may be a square, circle, oval, or other polygons.

The display module 20 includes a first substrate 21 and a plurality of light emitting elements disposed on the first substrate 21.

The first substrate 21 may be an insulating substrate. The first substrate 21 may include a transparent material. In one embodiment, for example, the first substrate 21 may include a transparent insulating material such as glass, quartz, or the like. The first substrate 21 may be a rigid substrate. However, the first substrate 21 is not limited thereto. The first substrate 21 may include a plastic such as PI or the like, and may have a flexible property such that the first substrate 21 may be curved, bent, folded, or rolled.

A plurality of pixel electrodes 22 may be disposed on one surface of the first substrate 21. Each pixel electrode 22 may be disposed for each pixel. The pixel electrodes 22 of the adjacent pixels may be separated from each other. A circuit layer (not shown) for driving each pixel electrode 22 may be disposed between the first substrate 21 and the pixel electrodes 22. The circuit layer may include a plurality of thin film transistors, capacitors, and the like.

The pixel electrode 22 may be a first electrode, e.g., an anode electrode of the light emitting element (or a light emitting diode). The pixel electrode 22 may have a stacked structure formed by stacking a material layer having a high work function, such as ITO, indium zinc oxide (“IZO”), zinc oxide (ZnO) and indium oxide (In₂O₃), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), or a combination thereof. The material layer having a high work function may be disposed above the reflective material layer and disposed closer to a light emitting layer 24. The pixel electrode 22 may have a multilayer structure such as ITO/Mg, ITO/MgF, ITO/Ag and ITO/Ag/ITO, but is not limited thereto.

A bank layer 23 may be disposed on one surface of the first substrate 21 along the boundaries of the pixels. The bank layer 23 may be disposed on the pixel electrodes 22, and openings may be defined through the bank layer 23 to expose the pixel electrodes 22. The bank layer 23 may include an organic insulating material such as acrylic resin, epoxy resin, phenolic resin, polyamide resin, PI resin, unsaturated polyester resin, polyphenylene resin, polyphenylenesulfide resin or benzocyclobutene (“BCB”). The bank layer 23 may also include an inorganic material.

The light emitting layer 24 is disposed on the pixel electrodes 22 exposed by the bank layer 23. In an embodiment, in which the display device is an organic light emitting display device, the light emitting layer 24 may include an organic layer containing an organic material. The organic layer may include the organic light emitting layer 24, and in some cases, may further include a hole injection/transport layer and/or an electron injection/transport layer, as an auxiliary layer for assisting light emission. In an alternative embodiment, when the display device is a micro LED display device, a nano LED display device or the like, the light emitting layer 24 may include an inorganic material such as an inorganic semiconductor.

A common electrode 25 may be disposed on the light emitting layer 24. The common electrode 25 may be in contact with not only the light emitting layer 24 but also the top surface of the bank layer 23.

The common electrode 25 may be commonly disposed across the pixels. The common electrode 25 may be a full surface electrode disposed over the entire surface without distinguishing the pixels. The common electrode 25 may be a second electrode (e.g., a cathode electrode) of a light emitting diode.

The common electrode 25 may include a material layer having a low work function, such as Li, Ca, LiF/Ca, LiF/Al, Al, Mg, Ag, Pt, Pd, Ni, Au Nd, Ir, Cr, BaF, Ba or a combination (e.g., a compound or mixture) thereof (e.g., a mixture of Ag and Mg). The common electrode 25 may further include a transparent metal oxide layer disposed on the material layer having a low work function.

The pixel electrode 22, the light emitting layer 24, and the common electrode 25 may constitute a light emitting element (e.g., an organic light emitting diode). Light emitted from the light emitting layer 24 may be emitted upward through the common electrode 25.

A thin film encapsulation structure 27 may be disposed on the common electrode 25. The thin film encapsulation structure 27 may include an encapsulation substrate or a second substrate. The encapsulation substrate may be an insulating substrate. The encapsulation substrate may include a transparent material. In one embodiment, for example, the encapsulation substrate may include a transparent insulating material such as glass, quartz, or the like. The encapsulation substrate may be a rigid substrate. The encapsulation substrate may be a same substrate as the first substrate 21, but not being limited thereto. Alternatively, the encapsulation substrate may have a different material, thickness, transmittance or the like from the first substrate 21. In one embodiment, for example, the encapsulation substrate may have a higher transmittance than the first substrate 21. The encapsulation substrate may be thicker or thinner than the first substrate 21.

However, the encapsulation substrate is not limited to those described above. The encapsulation substrate may include a plastic such as PI or the like, and may have a flexible property to be curved, bent, folded, or rolled.

A sealing member 26 may be disposed between the thin film encapsulation structure 27 and the first substrate 21. The sealing member 26 may be disposed in the non-display area NDA. The sealing member 26 may be disposed between the top surface of the bank layer 23 and the thin film encapsulation structure 27, and further, may be in direct contact with the top surface of the bank layer 23 and the thin film encapsulation structure 27 to couple the first substrate 21 and the thin film encapsulation structure 27.

The light control member 10′ described above may be disposed on the thin film encapsulation structure 27. The bonding member 30 may be disposed between the light control member 10 and the thin film encapsulation structure 27. The bonding member 30 may be in direct contact with an exposed absorptive pattern 17, an absorptive pattern protective layer 19, and the anisotropic prism 13 of the light control member 10′.

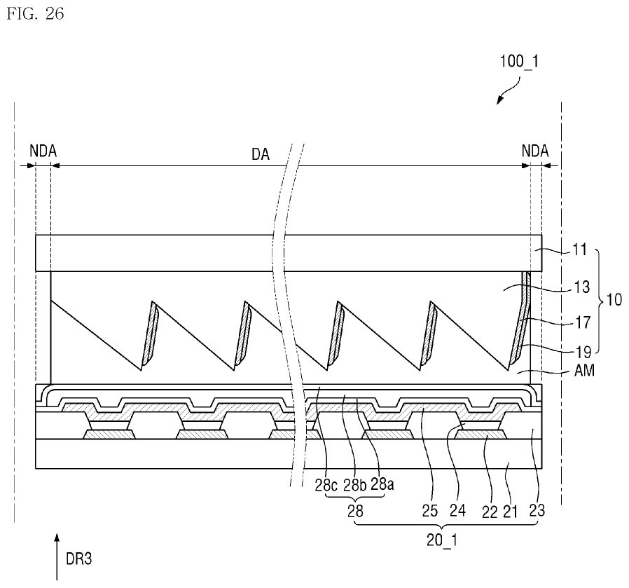

FIG. 26 is a cross-sectional view of a display device according to an alternative embodiment.

The display device 100_1 shown in FIG. 26 is substantially the same as the embodiment of FIG. 25 except that a thin film encapsulation structure 28 of a display module 20_1.

In such an embodiment, the thin film encapsulation structure 28 may include at least one thin film encapsulation layer. In one embodiment, for example, the thin film encapsulation layer may include a first inorganic layer 28a, an organic layer 28b, and a second inorganic layer 28c. Each of the first inorganic layer 28a and the second inorganic layer 28c may include silicon nitride, silicon oxide, or silicon oxynitride. The organic layer 28b may include an organic insulating material such as acrylic resin, epoxy resin, phenolic resin, polyamide resin, PI resin, unsaturated polyester resin, polyphenylene resin, polyphenylenesulfide resin or BCB.

The bonding member 30 may be disposed between the light control member 10′ and the thin film encapsulation structure 28. The bonding member 30 may be in direct contact with the exposed absorptive pattern 17, the absorptive pattern protective layer 19′, and the anisotropic prism 13 of the light control member 10, and the second inorganic layer 28c of the thin film encapsulation structure 28.

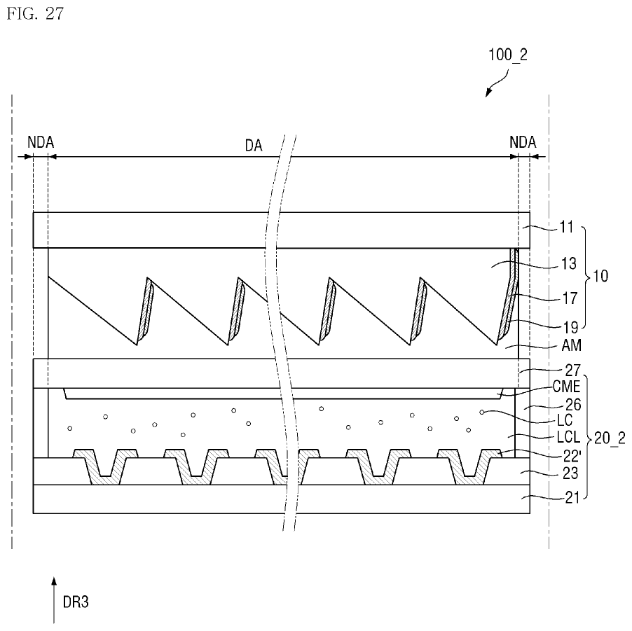

FIG. 27 is a cross-sectional view of a display device according to still another alternative embodiment.

The display device 100_2 shown in FIG. 27 is substantially the same as the embodiment of FIG. 25 except that the display device 100_2 is a liquid crystal display device including a display module 20_2 having a liquid crystal display panel.

In such an embodiment, the display device 100_2 may be a liquid crystal display device in which the display module 20_2 includes the liquid crystal display panel.

The display module 20_2 may include the first substrate 21, a second substrate 27 facing the first substrate 21, the bank layer 23 disposed on the first substrate 21, pixel electrodes 22′ disposed in the openings of the bank layer 23, a common electrode CME disposed on the bottom surface of the second substrate 27, and a liquid crystal layer LCL disposed between the common electrode CME and the pixel electrodes 22′ and having liquid crystal molecules LC.

The pixel electrodes 22′ are different from the pixel electrodes 22 of FIG. 25 in that the pixel electrodes 22′ are disposed on the bank layer 23 and specifically, on the side surfaces of the bank layer and a portion of the top surface of the bank layer.

The common electrode CME is different from the common electrode of FIG. 25 in that the common electrode CME is disposed on the second substrate 27 instead of the first substrate 21.

Other elements are substantially the same as those of FIG. 25, and thus, any repetitive detailed description thereof will be omitted.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A light control member comprising:
a substrate;
an anisotropic prism disposed on the substrate, wherein the anisotropic prim includes a first side surface extending at a first angle with respect to one surface of the substrate, and a second side surface extending at a second angle greater than the first angle with respect to the one surface of the substrate;
an absorptive pattern disposed on the second side surface of the anisotropic prism; and
an absorptive pattern protective layer disposed on the second side surface of the anisotropic prism and the absorptive pattern.

2. The light control member of claim 1, wherein the absorptive pattern is disposed between the absorptive pattern protective layer and the second side surface of the anisotropic prism.

3. The light control member of claim 2, wherein the absorptive pattern is disposed directly on the second side surface of the anisotropic prism.

4. The light control member of claim 3, wherein the absorptive pattern includes a first metal layer on the second side surface, an insulating layer on the first metal layer, and a second metal layer on the insulating layer.

5. The light control member of claim 4, wherein the anisotropic prism includes a resin.

6. The light control member of claim 5, wherein the absorptive pattern protective layer includes an inorganic insulating layer.

7. The light control member of claim 2, further comprising:
an etching stopper disposed on the first side surface and the second side surface of the anisotropic prism,
wherein the etching stopper is disposed directly on the first side surface and disposed between the second side surface and the absorptive pattern.

8. The light control member of claim 7, wherein the etching stopper includes at least one selected from indium tin oxide, ZrOx, HfOx, or A1203.

9. The light control member of claim 1, wherein the anisotropic prism includes a first prism portion in contact with the substrate, and a second prism portion connected to the first prism portion and having an anisotropic cross-sectional shape.

10. The light control member of claim 9, wherein the cross-sectional shape of the second prism portion includes a triangular shape.

11. The light control member of claim 9, wherein
each of the second prism portion and the absorptive pattern is provided in plural, and
the plurality of absorptive patterns are respectively disposed on the second side surfaces of the plurality of second prism portions.

12. The light control member of claim 1, wherein the absorptive pattern covers at least a portion of the second side surface of the anisotropic prism and exposes a part of the first side surface.

13. A light control member comprising:
a substrate;
an anisotropic prism disposed on the substrate, wherein the anisotropic prism includes a first side surface extending at a first angle with respect to one surface of the substrate, and a second side surface extending at a second angle greater than the first angle with respect to the one surface of the substrate; and
an absorptive pattern disposed on the second side surface of the anisotropic prism,
wherein the absorptive pattern is disposed directly on the second side surface, and
the absorptive pattern includes a metal layer.

14. The light control member of claim 13, further comprising:
an absorptive pattern protective layer disposed on the second side surface of the anisotropic prism and the absorptive pattern.

15. The light control member of claim 13, further comprising:
an etching stopper disposed on the first side surface and the second side surface of the anisotropic prism,
wherein the etching stopper is disposed directly on the first side surface and disposed between the second side surface and the absorptive pattern.

16. A display device comprising:
a light emitting element disposed on a first substrate; and
a light control member disposed on the light emitting element,
wherein the light control member includes:
a substrate;
an anisotropic prism disposed on the substrate, wherein the anisotropic prism includes a first side surface extending at a first angle with respect to one surface of the substrate, and a second side surface extending at a second angle greater than the first angle with respect to the one surface of the substrate;
an absorptive pattern disposed on the second side surface of the anisotropic prism; and
an absorptive pattern protective layer disposed on the second side surface of the anisotropic prism and the absorptive pattern.

17. The display device of claim 16, wherein the light emitting element includes a first electrode disposed on the first substrate, a second electrode opposite to the first electrode, and a light emitting layer disposed between the first electrode and the second electrode.

18. The display device of claim 16, further comprising:
a second substrate facing the first substrate and disposed on the light emitting element,
wherein the second substrate seals the light emitting element, and
the light control member is disposed on the second substrate.

19. The display device of claim 16, further comprising:
an encapsulation layer disposed on the light emitting element to seal the light emitting element,
wherein the light control member is disposed on the encapsulation layer.

20. A method of manufacturing a display device, the method comprising:
forming a light control member; and
bonding the light control member and a display panel to each other,
wherein the forming the light control member includes:
providing, on a substrate, an anisotropic prism including a first side surface extending at a first angle with respect to one surface of the substrate, and a second side surface extending at a second angle greater than the first angle with respect to the one surface of the substrate;
providing an absorptive pattern on the second side surface of the anisotropic prism; and
providing an absorptive pattern protective layer disposed on the second side surface of the anisotropic prism and the absorptive pattern.

21. A method of manufacturing a display device, the method comprising:
forming a light control member; and
bonding the light control member and a display panel to each other,
wherein the forming the light control member includes:
providing, on a substrate, an anisotropic prism including a first side surface extending at a first angle with respect to one surface of the substrate, and a second side surface extending at a second angle greater than the first angle with respect to the one surface of the substrate; and
providing an absorptive pattern on the second side surface of the anisotropic prism,
wherein the absorptive pattern is disposed directly on the second side surface, and
the absorptive pattern is formed using only one material.
